(19) United States
(12) Patent Application Publication
(10) Pub. No.: US 2010/0104403 A1
(43) Pub. Date: Apr. 29, 2010

(54) APPARATUS FOR TRANSFERRING A WAFER

(76) Inventors: Sang-Bum Cho, Seoul (KR); Kang-Il Heo, Gyeonggi-do (KR); Byoung-Jin Jung, Seoul (KR); Sung-Don Ahn, Seoul (KR); Jung-Ho Choi, Chungnam (KR); Seung-Hee Gang, Gyeonggi-do (KR); Hwi-Souck Chang, Gyeonggi-do (KR)

Correspondence Address: DALY, CROWLEY, MOFFORD & DURKEE, LLP, SUITE 301A, 354A TURNPIKE STREET, CANTON, MA, 02021-2714, US

(21) Appl. No.: 12/530,664

(22) PCT Filed: Mar. 3, 2008
(86) PCT No.: PCT/KR08/01205

§ 371 Date: Sep. 10, 2009

(30) Foreign Application Priority Data
Mar. 12, 2007 (KR) 10-2007-0023831

(51) Int. Cl. H01L 21/68

(52) U.S. Cl. 414/222.13

(57) ABSTRACT

An apparatus for transferring a wafer includes a ceramic blade, an electrode, a plurality of pads, a coating layer and a robot arm. The blade supports the wafer, and the electrode is disposed inside the blade. Electric power is applied to the electrode to generate an electrostatic force for holding the wafer. The pads are disposed on an upper surface of the blade, and thus frictional forces may be provided between the wafer and the pads. The coating layer is disposed on the blade. The robot arm is connected with the blade to move the blade.

### TECHNICAL FIELD

The present invention relates to a wafer-transferring apparatus. More particularly, the present invention relates to a wafer-transferring apparatus including a blade to hold a wafer using an electrostatic force.

### BACKGROUND ART

Generally, semiconductor devices may be manufactured by forming layers on a silicon wafer used as a semiconductor substrate and forming circuit patterns from the layers. The circuit patterns may be formed by sequentially or repeatedly performing unit processes, such as a chemical vapor deposition (CVD) process, sputtering process, a photolithography process, an etching process, an ion implantation process, a chemical mechanical polishing (CMP) process, and the like. The wafer may be held and transferred by a wafer-transferring apparatus during the unit processes.

The wafer-transferring apparatus may hold the wafer using a frictional force, a vacuum force, an electrostatic force, etc. The wafer-transferring apparatus using the electrostatic force may be used under a vacuum atmosphere and a blade of the wafer-transferring apparatus may include an electrode and a dielectric to generate the electrostatic force. The dielectric may include a ceramic material and fine holes or pores may be formed in a surface portion of the dielectric in a manufacturing process. The fine holes may be filled with moisture and impurities in the air, and thus the wafer may be contaminated by the moisture and the impurities.

Meanwhile, a high voltage may be applied to the electrode and a thickness of the dielectric may be reduced to increase the electrostatic force. In such a case, the dielectric may be damaged by the high voltage, and thus the wafer may be electrically connected with the electrode through the damaged dielectric, which may electrify the wafer. As a result, the wafer may be damaged by the electrification.

Further, because electric charge may not be discharged sufficiently from the dielectric due to the high voltage, it may be difficult to easily detach the wafer from the blade. To solve the problem, a voltage having an opposite polarity to that of a voltage for generating the electrostatic force may be applied to the electrode.

### DISCLOSURE OF INVENTION

### Technical Problem

Example embodiments of the present invention provide an apparatus for transferring a wafer capable of preventing contamination of the wafer and firmly holding the wafer.

### Technical Solution

An apparatus for transferring a wafer, according to one aspect of the present invention, may include a ceramic blade supporting the wafer; an electrode disposed inside the blade, wherein electric power is applied to the electrode to generate an electrostatic force for holding the wafer; a plurality of pads disposed on the blade, wherein the pads provide frictional forces between the wafer and the pads to prevent the wafer from moving on the blade; and a robot arm connected with the blade to move the blade.

In some example embodiments of the present invention, a gap between the pads and the electrode may be greater than that between an upper surface of the electrode and an upper surface of the blade.

In some example embodiments of the present invention, the pads may include silicon, polyimide, rubber, and the like. These materials may be used alone or in a combination thereof.

In some example embodiments of the present invention, the apparatus may further include a coating layer disposed on an upper surface portion of the blade except portions on which the pads are disposed.

In some example embodiments of the present invention, the coating layer may include oxide, nitride, oxynitride, and the like. These materials may be used alone or in a combination thereof.

In some example embodiments of the present invention, the coating layer may be denser than the blade.

In some example embodiments of the present invention, the coating layer may be formed by a chemical vapor deposition (CVD) process, a plasma-enhanced chemical vapor deposition (PECVD) process, a high-density plasma chemical vapor deposition (HDP-CVD) process, a sputtering process, and the like.

In some example embodiments of the present invention, the electrode may include a first electrode to which a positive voltage is applied and a second electrode to which a negative voltage is applied.

An apparatus for transferring a wafer, according to another aspect of the present invention, may include a ceramic blade supporting the wafer; an electrode disposed inside the blade, wherein electric power is applied to the electrode to generate an electrostatic force for holding the wafer; a coating layer disposed on the blade, wherein the coating layer is denser than the blade; and a robot arm connected to the blade to move the blade.

### Advantageous Effects

In accordance with the example embodiments of the present invention as described above, an electrostatic force required to hold a wafer may be reduced by frictional forces between pads disposed on a blade and the wafer, thereby reducing electric power that is applied to an electrode to generate the electrostatic force. Thus, damage to the wafer that may occur by electrifying the wafer may be prevented.

Further, a coating layer on the blade may have a density higher than that of the blade so as to prevent the blade from being contaminated by moisture and impurities in the air, thereby reducing contamination of the wafer.

### BRIEF DESCRIPTION OF THE DRAWINGS

The above and other advantages of the present invention will become more apparent by describing example embodiments thereof in detail with reference to the accompanying drawings, in which:

FIG. 1 is a plan view illustrating an apparatus for transferring a wafer in accordance with an example embodiment of the present invention;

FIG. 2 is a cross-sectional view taken along a line II-II′ in FIG. 1;

FIG. 3 is a plan view illustrating an apparatus for transferring a wafer in accordance with another example embodiment of the present invention;

FIG. 4 is a cross-sectional view taken along a line IV-IV′ in FIG. 3;

FIG. 5 is a plan view illustrating an apparatus for transferring a wafer in accordance with still another example embodiment of the present invention; and

FIG. 6 is a cross-sectional view taken along a line VI-VI′ in FIG. 5.

### BEST MODE FOR CARRYING OUT THE INVENTION

The present invention is described more fully hereinafter with reference to the accompanying drawings, in which example embodiments of the present invention are shown. The present invention may, however, be embodied in many different forms and should not be construed as limited to the example embodiments set forth herein. Rather, these embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on” or “connected to” another element or layer, it can be directly on or connected to the other element or layer or intervening elements or layers may be present. In contrast, when an element is referred to as being “directly on” or “directly connected to” another element or layer, there are no intervening elements or layers present. Like reference numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “lower,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments of the present invention are described herein with reference to cross-sectional illustrations that are schematic illustrations of idealized embodiments (and intermediate structures) of the present invention. As such, variations from the shapes of the illustrations as a result, for example, of manufacturing techniques and/or tolerances, are to be expected. Thus, example embodiments of the present invention should not be construed as limited to the particular shapes of regions illustrated herein but are to include deviations in shapes that result, for example, from manufacturing. The regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

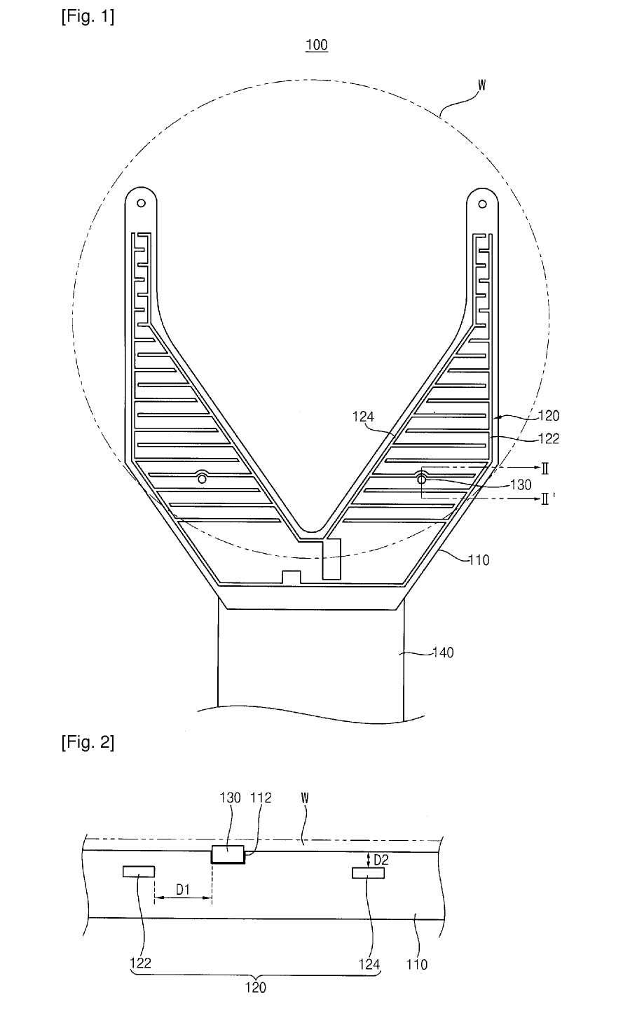

FIG. 1 is a plan view illustrating an apparatus for transferring a wafer in accordance with an example embodiment of the present invention, and FIG. 2 is a cross-sectional view taken along a line II-II′ in FIG. 1.

Referring to FIGS. 1 and 2, an apparatus 100 for transferring a wafer W may include a blade 110, an electrode 120, a plurality of pads 130 and a robot arm 140.

The blade 110 may include a ceramic material and may support the wafer W. The blade 110 may have a generally U-shaped form.

The electrode 120 may be disposed inside the blade 110 to generate an electrostatic force to hold the wafer W. In accordance with an example embodiment of the present invention, the electrode 120 may include a first electrode 122 and a second electrode 124. The first and second electrodes 122 and 124 may extend along outer portions and inner portions of the blade, respectively. Further, the first and second electrodes 122 and 124 may each have a plurality of electrode pins extending toward each other and may not be connected with each other. The first and second electrodes 122 and 124 may be connected with power sources different from each other, respectively. For example, a positive voltage may be applied to the first electrode 122 and a negative voltage may be applied to second electrode 124. However, one electrode may be used to generate the electrostatic force.

The electrode 120 may include metal or metal alloy, and examples of the metal that may be used for the electrode 120 may include tungsten, molybdenum, and the like.

An upper portion of the blade 110 between the electrode 120 and the wafer W may serve as a dielectric.

The pads 130 may be disposed on an upper surface of the blade 110. Frictional forces may be provided between the wafer W and the pads 130 so that the wafer W may be prevented from moving or sliding on the blade 110.

In accordance with an example embodiment of the present invention, as shown in FIG. 2, the pads 130 may be inserted in grooves that may be formed in an upper surface portion of the blade 110. The pads 130 may be projected from the upper surface of the blade 110 to come in contact with the wafer W. When a projection height of the pads 130 is excessively high, the wafer W may be warped by the pads 130. Further, because an air space between the wafer W and the blade 110 may serve as a dielectric, the electrostatic force by the electrode 120 may be decreased. For example, the projection height of the pads 130 may be in a range of a few micrometers to a few tens of micrometers or less than about 100 micrometers. Alternatively, upper surfaces of the pads 130 may be disposed on the same plane as the upper surface of the blade 110.

In accordance with another example embodiment of the present invention, the pads 130 may be disposed on the upper surface of the blade 110. A thickness of the pads 130 may be in a range of a few micrometers to a few tens of micrometers or less than about 100 micrometers.

Meanwhile, when a gap D1 between the pads 130 and the electrode 120 is equal to or less than a gap D2 between an upper surface of the electrode 120 and the upper surface of the blade 110, the electric power may be applied from the electrode 120 through the pads 130, which may electrify the wafer W, such that the wafer W may be damaged by the electrification. The gap D1 between the pads 130 and the electrode 120 may be greater than the gap D2 between the upper surface of the electrode 120 and the upper surface of the blade 110.

Examples of a material that may be used for the pads 130 may include silicon, polyimide, rubber, and the like. These materials may be used alone or in a combination thereof.

The electrostatic force required to hold the wafer W may be reduced by the frictional force between the pads 130 and the wafer W. That is, it may be possible to reduce the electric power that is applied to the electrode 120 or to increase a thickness of the upper portion of the blade 110, for example, the gap D2. Thus, the wafer W may be prevented from being damaged by a high voltage or an electric leakage due to damage to the blades 110.

Further, electric charge accumulated in a lower portion of the wafer W may be decreased according as the required electrostatic force is reduced. Thus, the wafer W may be easily detached from the blade 110. Meanwhile, the air space between the wafer W and the blade 110 may serve as a dielectric, and than the electric charge accumulated in the lower portion of the wafer W, thereby more easily detaching the wafer W.

The robot arm 140 may be connected with the blade 110 and may rotate centering on a rotary shaft (not shown). The blade 110 may be moved by the rotation of the robot arm 140 so as to transfer the wafer W held by the blade 110.

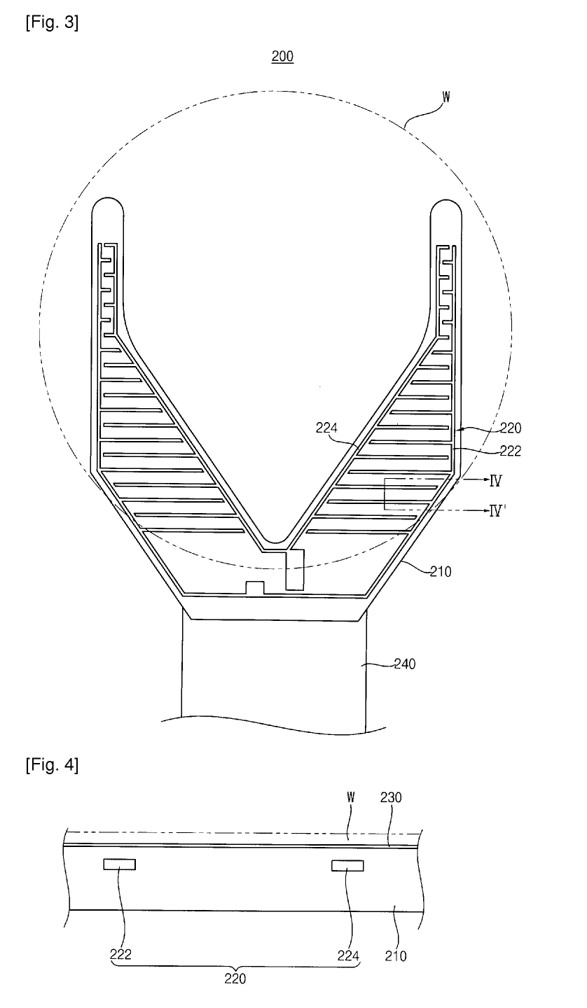

FIG. 3 is a plan view illustrating another apparatus for transferring a wafer in accordance with an example embodiment of the present invention, and FIG. 4 is a cross-sectional view taken along a line IV-IV′ in FIG. 3.

Referring to FIGS. 3 and 4, an apparatus 200 for transferring wafer W may include a blade 210, an electrode 220, a coating layer 230 and a robot arm 240.

Detailed descriptions of the blade 210, the electrode 220 and the robot arm 240 except for the coating layer 230 will be omitted because these elements are similar to those already described with reference to FIGS. 1 and 2.

The coating layer 230 may be disposed on the blade 210 and may include oxide, nitride, oxynitride, and the like. For example, the coating layer 230 may include silicon oxide (SiO2), silicon nitride (SiN), silicon oxynitride (SiON), aluminum oxide (Al2O3), aluminum nitride (AlN), titanium oxide (TiO2), titanium nitride (TiN), and the like. The coating layer 230 may be formed by a chemical vapor deposition (CVD) process, a plasma-enhanced chemical vapor deposition (PECVD) process, a high-density plasma chemical vapor deposition (HDP-CVD) process, a sputtering process, and the like. Thus, the coating layer 230 may be denser than the blade 210 that is formed by a sintering process. That is, the coating layer 230 may have a density higher than that of the blade 210. Further, the coating layer 230 may have improved mechanical properties in comparison with the blade 210. Thus, it may be difficult for fine holes to be formed in a surface portion of the coating layer 230. As a result, the wafer W may be prevented from being contaminated by moisture or impurities in the air.

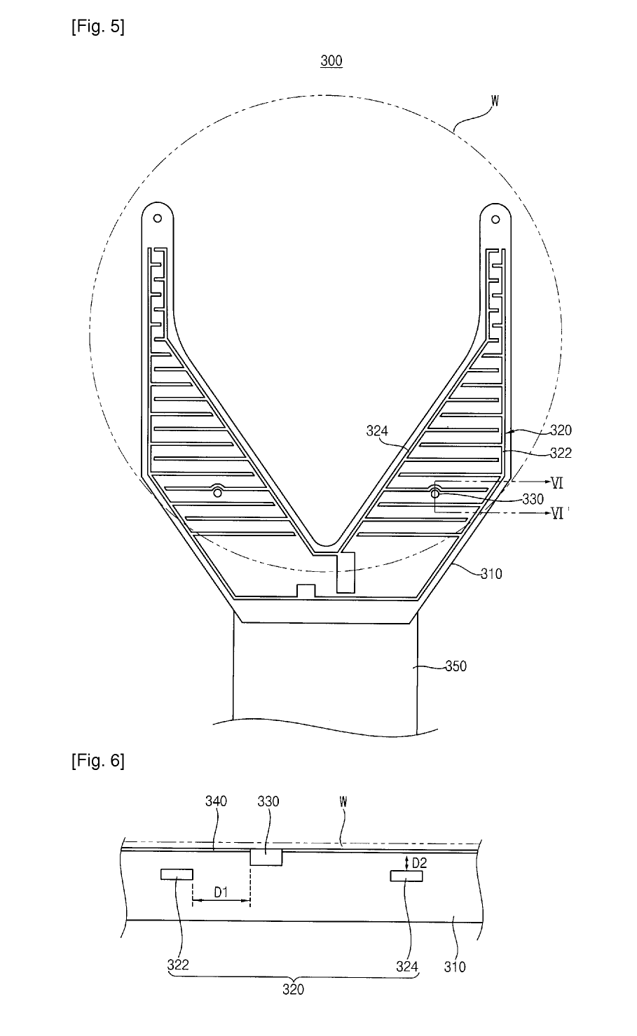

FIG. 5 is a plan view illustrating still another apparatus for transferring a wafer in accordance with an example embodiment of the present invention, and FIG. 6 is a cross-sectional view taken along a line VI-VI′ in FIG. 5.

Referring to FIGS. 5 and 6, an apparatus 300 for transferring a wafer W may include a blade 310, an electrode 320, a plurality of pads 330, a coating layer 340 and a robot arm 350.

Detailed descriptions of the blade 310, the electrode 320, the pads 330 and the robot arm 350 will be omitted because these elements are similar to those already described with reference to FIGS. 1 and 2.

The coating layer 340 may be disposed on an upper surface portion of the blade 310 except portions on which the pads 330 are disposed. Further detailed descriptions of the coating layer 340 will be omitted because the coating layer 340 is similar to that already described with reference to FIGS. 3 and 4.

### INDUSTRIAL APPLICABILITY

As described above, a wafer-transferring apparatus according to example embodiments of the present invention may include a plurality of pads disposed on a blade. Thus, an electrostatic force required to hold the wafer may be relatively reduced in comparison with a conventional art. As a result, the wafer may be prevented from being damaged by a high voltage or electrification due to damage to the blade.

Further, electric charge accumulated in the wafer may be decreased because the required electrostatic force may be reduced due to frictional forces of the pads and further also reduced by an air space between the wafer and the blade. Thus, the wafer may be easily detached from the blade.

Meanwhile, the wafer-transferring apparatus may include a coating layer disposed on the blade and having a density higher than that of the blade. It may be difficult for fine holes to be formed in a surface portion of the coating layer, and thus the wafer may be prevented from being contaminated by moisture or impurities in the air.

Although the example embodiments of the present invention have been described, it is understood that the present invention should not be limited to these example embodiments but various changes and modifications can be made by those skilled in the art within the spirit and scope of the present invention as hereinafter claimed.

1. An apparatus for transferring a wafer comprising:
a ceramic blade supporting the wafer;
an electrode disposed inside the blade, wherein electric power is applied to the electrode to generate an electrostatic force for holding the wafer;
a plurality of pads disposed on the blade, wherein the pads provide frictional forces between the wafer and the pads to prevent the wafer from moving on the blade; and
a robot arm connected with the blade to move the blade.

2. The apparatus of claim 1, wherein a gap between the pads and the electrode is greater than that between an upper surface of the electrode and an upper surface of the blade.

3. The apparatus of claim 1, wherein the pads comprise silicon, polyimide or rubber.

4. The apparatus of claim 1, further comprising a coating layer disposed on an upper surface portion of the blade except portions on which the pads are disposed.

5. The apparatus of claim 4, wherein the coating layer comprises oxide, nitride or oxynitride.

6. The apparatus of claim 4, wherein the coating layer is denser than the blade.

7. The apparatus of claim 4, wherein the coating layer is formed by any one selected from the group consisting of a chemical vapor deposition process, a plasma-enhanced chemical vapor deposition process, a high-density plasma chemical vapor deposition process and a sputtering process.

8. The apparatus of claim 1, wherein the electrode comprises a first electrode to which a positive voltage is applied and a second electrode to which a negative voltage is applied.

9. An apparatus for transferring a wafer comprising:
a ceramic blade supporting the wafer;
an electrode disposed inside the blade, wherein electric power is applied to the electrode to generate an electrostatic force for holding the wafer;
a coating layer disposed on the blade, wherein the coating layer is denser than the blade; and
a robot arm connected to the blade to move the blade.
